(19) United States
(12) Patent Application Publication
(10) Pub. No.: US 2007/0136015 A1
(43) Pub. Date: Jun. 14, 2007

(54) Diagnosis apparatus for diagnosing state of equipment

(75) Inventors: Hideaki Suzuki, Hitachi (JP); Taizo Miyazaki, Hitachi (JP); Koichiro Tanikoshi, Hitachinaka (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi, Ltd., Chiyoda-ku (JP)

(21) Appl. No.: 11/605,345

(22) Filed: Nov. 29, 2006

(30) Foreign Application Priority Data
Nov. 29, 2005 (JP) 2005-343839

(51) Int. Cl. G01R 29/02

(52) U.S. Cl. 702/79; 370/241

(57) ABSTRACT

A diagnosis apparatus for diagnosing state of equipment includes an interval estimation unit which receives time series information from diagnosis object equipment and detects a change point of the time series information, a state estimation unit which receives the time series information from the diagnosis object equipment and change point information from the interval estimation unit, divides the time series information temporally with the change point as a boundary, and estimates a state of the equipment from before and after relation of an interval or relation with another time series information per divided interval, and an equipment diagnosis unit which diagnoses the equipment according to an estimated state.

### BACKGROUND OF THE INVENTION

The present invention relates to a diagnosis apparatus for diagnosing state of equipment.

In equipment for general use such as a car a mechanism to control and protect the equipment is provided within a control device of the equipment and when an abnormality is detected an alarm is displayed on a display panel, etc. to inform a user of the abnormality.

Also, regarding the car, as regular inspections are obligatory by law a specialist diagnoses whether there is an abnormality or not at the inspection and if there is an abnormality the equipment is supposed to be repaired and maintained.

Recently, there has been a proposition to provide a so-called drive recorder in a car body as a recording device similarly to a flight recorder in an airplane and to utilize its recorded data in a variety of forms (see, for example, JP-A-2002-073153 (pages 3, 4, FIG. 1-FIG. 4)).

The recording device records such as how a driver operated at an accident, whether the car was operating normally or not, etc. Also, preventive maintenance to record an abnormality indication such that the driver cannot judge to utilize the record at the inspection and to maintain before a fault or an accident occurs has been considered.

In diagnosis object equipment such as a car, as the control information of the inner part of the equipment is of a variety of kinds and additionally is of a great amount, the development of a diagnosis technique which utilizes a computer is desired (see, for example, JP-A-2005-004658 (pages 6-11, FIG. 1-FIG. 4) (corresponding to U.S. Pat. No. 7,016,797), JP-A-2002-217811 (page 4, FIG. 4 and FIG. 5)).

In particular, in the case where a large amount of time series information is treated such as in the case of the car its diagnosis depends on the experience of the skilled technician and its limit has been indicated as the car is equipped with higher function.

### SUMMARY OF THE INVENTION

The invention of JP-A-2005-004658 detects a state in which there has been a change which is different from the normal state as an abnormal state to detect an abnormal intrusion in a computer network.

The invention of JP-A-2002-217811 detects whether a mobile object is moving or stopping from a radio wave state of a communication terminal of the mobile object.

However, as to an object such as a car with which it is difficult to decide in which state it is in only by looking at the time series information partly because a change point of the sate is not clear and the state of the equipment changes in various ways depending on operation environment and operation condition, there remains a problem in processing its time series information.

For example, in the case of the car even if the car is running normally, a driving environment changes depending on whether the car is running on a level ground or it is intended to climb up a sloping road.

In the present car it is often that there is not special sensor information to estimate the slope which is the operation environment.

An object of the present invention is to provide a diagnosis apparatus for diagnosing state of equipment which estimates the state of the equipment based on the time series information of the equipment considering not only the operation state of the equipment but also the operation environment and the operation condition, and diagnoses the state of the equipment according to an estimated state.

In order to accomplish the above-mentioned object the present invention proposes a diagnosis apparatus for diagnosing state of equipment includes an interval estimation unit which receives time series information from diagnosis object equipment and detects a change point of the time series information, a state estimation unit which receives the time series information from the diagnosis object equipment and change point information from the interval estimation unit, divides the time series information temporally with the change point as a boundary, and estimates a state of the equipment from before and after relation of an interval or a relation with another time series information per divided interval, and an equipment diagnosis unit which diagnoses the equipment according to an estimated state.

The interval estimation unit is provided with a feature amount extraction unit and an interval detection unit, the feature amount extraction unit calculates a feature amount of the time series information received from the diagnosis object equipment, sends a calculated feature amount and the time series information before the calculation process to the interval detection unit, the interval detection unit divides the time series information temporally using a received feature amount and returns divided interval information to the feature amount extraction unit, the feature amount extraction unit calculates another feature amount per divided interval based on received interval information, sends another calculated feature amount to the interval detection unit, and, the feature amount extraction unit and the interval detection unit alternately perform the calculation of the feature amount and the calculation of the interval information and output final interval information and feature amount to the state estimation unit.

The state estimation unit is provided with an interval classification unit, an interval relation decision unit, and a state decision unit, the interval classification unit calculates to which state each interval is classified using received interval information and feature amount, the interval relation decision unit, which previously keeps state transition information corresponding to the equipment, compares primary classification information with the state transition information which it previously keeps, decides whether a state of the classified interval is correct or not, the state decision unit searches part in which interval relation is not correct among received decision results, modifies the classification of the interval to be correct relation, and outputs interval information and state information of each to the equipment diagnosis unit.

In the diagnosis apparatus for diagnosing state of equipment of the present invention, as it distinguishes the operation state, the operation environment, and the operation condition of the equipment, it estimates the state of the equipment based on the before and after relation of the time series information, and diagnoses the state of the equipment properly according to the estimated state, the diagnosis precision can be enhanced.

Other objects, features and advantages of the invention will become apparent from the following description of the embodiments of the invention taken in conjunction with the accompanying drawings.

### BRIEF DESCRIPTION OF THE DRAWINGS

FIG. 1 is a block diagram showing a configuration of an embodiment of a diagnosis apparatus for diagnosing state of equipment according to the present invention.

FIG. 2 is a block diagram showing an example of an internal configuration of an interval estimation unit and a state estimation unit in the diagnosis apparatus for diagnosing state of equipment according to the present invention.

FIG. 3 is a diagram showing the kinds of the state in a car and the interrelationship of these states.

FIG. 4 is a time chart showing an example of time series information.

FIG. 5 is a time chart showing relation between the time series information, a feature amount and an interval division.

FIGS. 6A-6C are tables showing the feature amounts in the intervals from t11 to t18.

FIG. 7 is a time chart showing relation between the time series information, the feature amount and the interval division.

FIG. 8 is a time chart showing relation between the time series information, the feature amount and the interval division.

FIG. 9 is a time chart showing relation between the time series information, the feature amount and the interval division.

### DETAILED DESCRIPTION OF THE EMBODIMENT

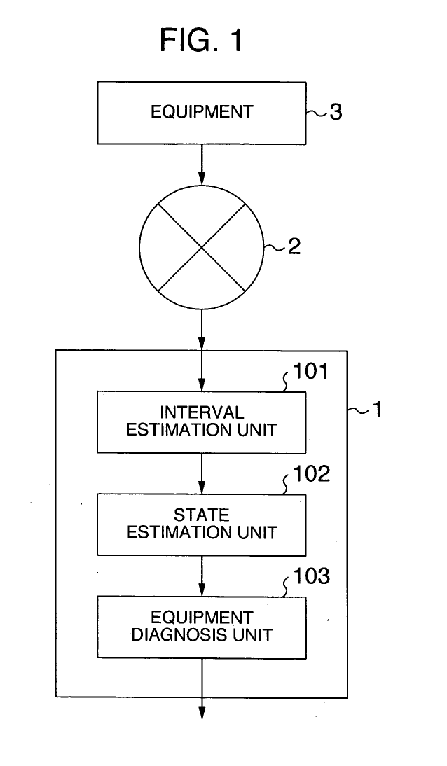

Next, an embodiment of the diagnosis apparatus for diagnosing state of equipment according to the present invention will be explained referring to FIG. 1-FIG. 9.

FIG. 1 is a block diagram showing a configuration of an embodiment of the diagnosis apparatus for diagnosing state of equipment according to the present invention.

A diagnosis apparatus for diagnosing state of equipment 1 receives time series information from diagnosis object equipment 3 via a network 2, diagnoses the state of the equipment 3, and outputs a result thereof. The time series information is a series of information which records state information such as a variety of kinds of control information and sensor information regarding the state of the equipment according to the time order.

For example, in the case of the car, data which records information such as a speed, a number of revolutions of engine, a degree of opening of accelerator, fuel consumption according to the time is the time series information.

The diagnosis apparatus for diagnosing state of equipment 1 is provided with an interval estimation unit 101, a state estimation unit 102, and an equipment diagnosis unit 103.

The interval estimation unit 101 receives the time series information from the diagnosis object equipment 3 via the network 2 and detects a change point of the time series information.

The state estimation unit 102 receives the time series information from the diagnosis object equipment 3 and change point information from the interval estimation unit 101 and estimates the state of the equipment from before and after relation between the states.

The equipment diagnosis unit 103 diagnoses selecting an appropriate diagnosis method based on state information of the equipment estimated at the state estimation unit 102 and outputs a diagnosed result.

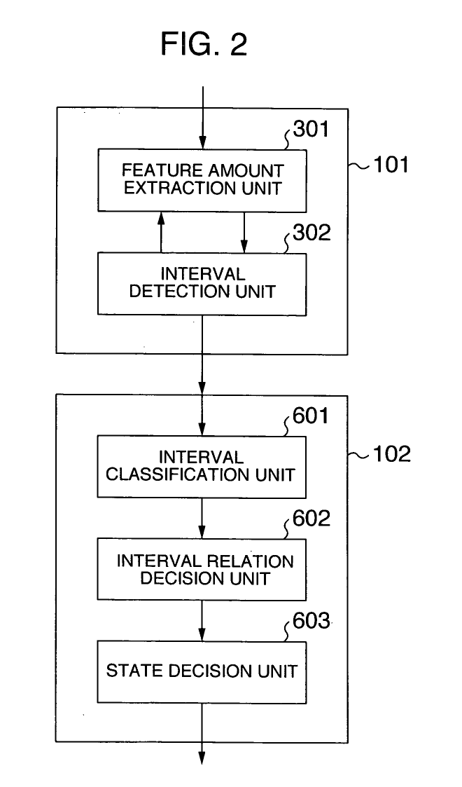

FIG. 2 is a block diagram showing an example of an internal configuration of the interval estimation unit 101 and the state estimation unit 102 in the diagnosis apparatus for diagnosing state of equipment according to the present invention.

The interval estimation unit 101 is provided with a feature amount extraction unit 301 and an interval detection unit 302.

The feature amount extraction unit 301 calculates a feature amount of the time series information received from the diagnosis object equipment 3 via the network 2 and sends a calculated feature amount and the time series information before the calculation process to the interval detection unit 302.

The interval detection unit 302 divides the time series information temporally using a received feature amount. The interval detection unit 302 returns divided interval information to the feature amount extraction unit 301.

The feature amount extraction unit 301 calculates another feature amount per divided interval based on received interval information and sends another calculated feature amount to the interval detection unit 302.

In this way, the feature amount extraction unit 301 and the interval detection unit 302 alternately perform the calculation of the feature amount and the calculation of the interval information and send final interval information and feature amount as an output to the state estimation unit 102.

The state estimation unit 102 is provided with an interval classification unit 601, an interval relation decision unit 602, and a state decision unit 603.

The interval classification unit 601 calculates to which state each interval is classified using received interval information and feature amount. As a specific calculation method it compares and refers the trend value of the feature amount per state and primarily classifies in which state each interval is.

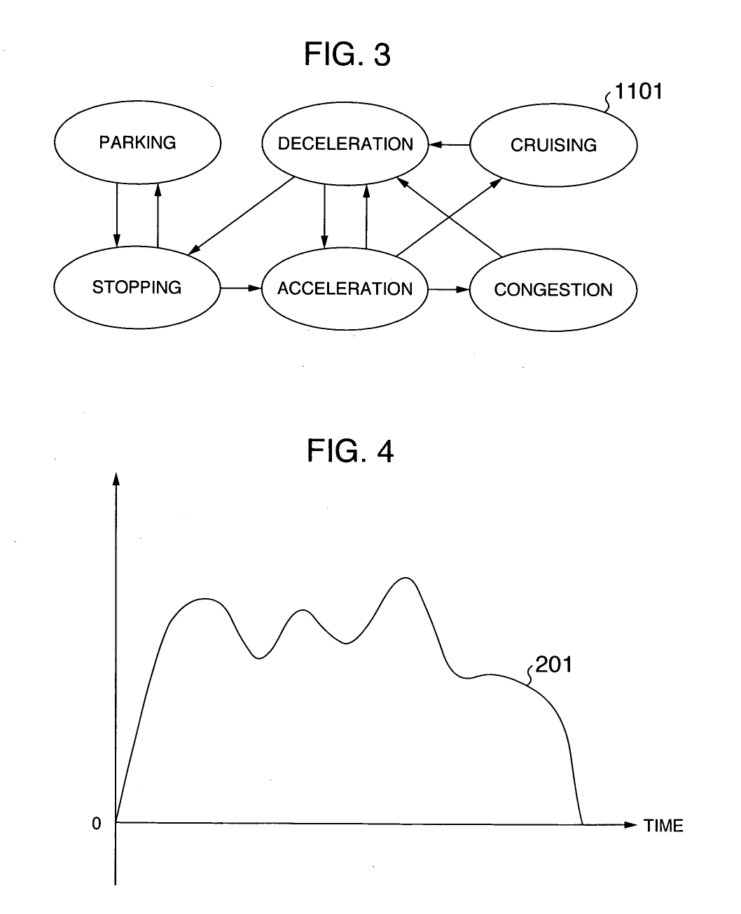

FIG. 3 is a diagram showing the kinds of the state in a car and the correlation of these states.

A state transition diagram 1101 shows running states in the normal use of the car, and there are six states as “parking”, “stopping”, “acceleration”, “deceleration”, “cruising”, and “congestion”, and the arrow represents the possible transition from which state to which state.

For example, the “stopping” represents a state in which the engine of the car is started but the car is not running. Further, the “cruising” means that the car is running regularly within a certain speed range, to the contrary the “congestion” means that the car is running in a traffic condition in which cars are in a congested condition at a speed lower than a certain speed.

FIG. 4 is a time chart showing an example of the time series information. The operation of the interval estimation unit 101 will be explained using the time series information of FIG. 4.

The time series information of this example is speed information in the car. Speed information of the car 201 starts from speed 0, continues to change with the lapse of the time and finally ends with speed 0.

The interval estimation unit 101 receives the speed information 201 from the diagnosis object equipment 3 via the network 2. The equipment 3 is such as a car control unit which controls the speed information and is equipped in the internal part of the car, etc.

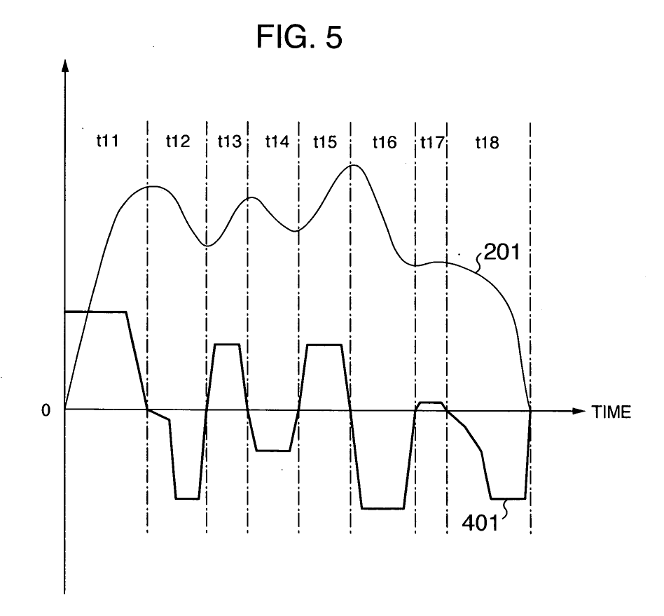

FIG. 5 is a time chart showing the relation between the time series information, the feature amount, and the interval division.

The feature amount extraction unit 301 within the interval estimation unit 101 calculates feature amount 401 from received speed information. The feature amount 401 is acceleration grade information which is a primary linear differential value calculated from input speed information. The feature amount extraction unit 301 sends calculated acceleration grade information to the interval detection unit 302 as the feature amount 401.

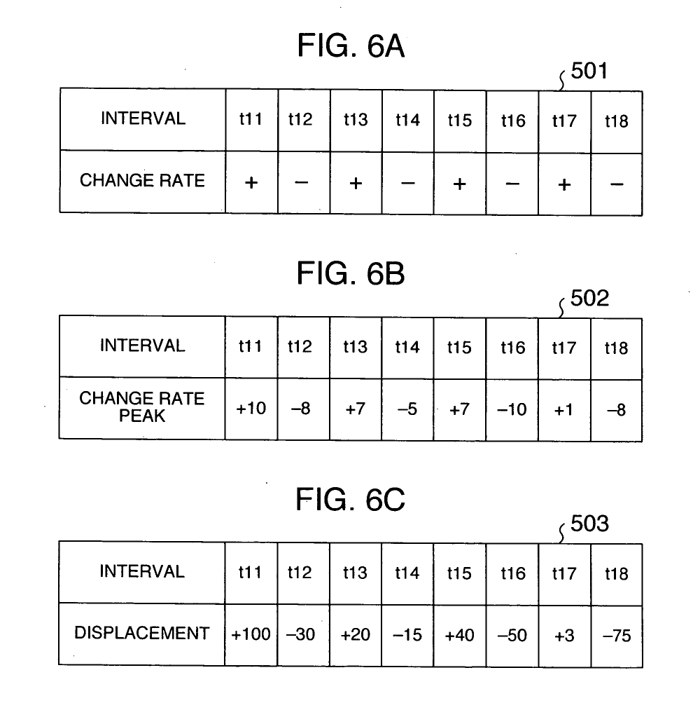

The interval detection unit 302 calculates the time when received acceleration grade information becomes 0, decides the time to be a change point of the time series information, and divides the time series information (speed information) temporally in intervals from t11 to t18. FIGS. 6A-6C are tables showing the feature amounts in the intervals from t11 to t18.

The interval detection unit 302 returns time divided interval information to the feature amount extraction unit 301. The feature amount extraction unit 301 receives the interval information, calculates three kinds of feature amount as change rate 501, change rate peak 502, and displacement 503 from the time series information per interval and sends them again to the interval detection unit 302.

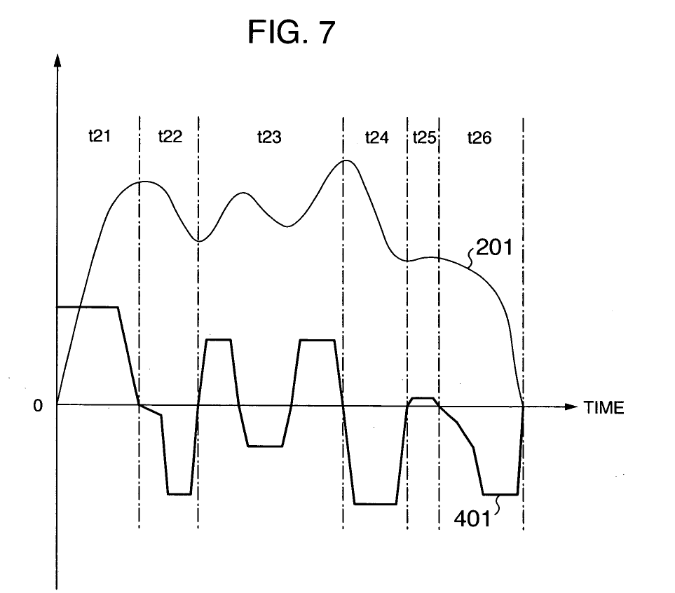

FIG. 7 is a time chart showing the relation between the time series information, the feature amount, and the interval division.

When the interval detection unit 302 updates the interval information using the change rate peak 502, the interval information is divided again in six intervals from t21 to t26 as shown in FIG. 7.

In this decision rule among the intervals in which the absolute value of the change rate peak 502 is before update the intervals in which the absolute values are less than 8 are decided to be the same intervals. As a result, from t13 to t15 are decided to be the same interval.

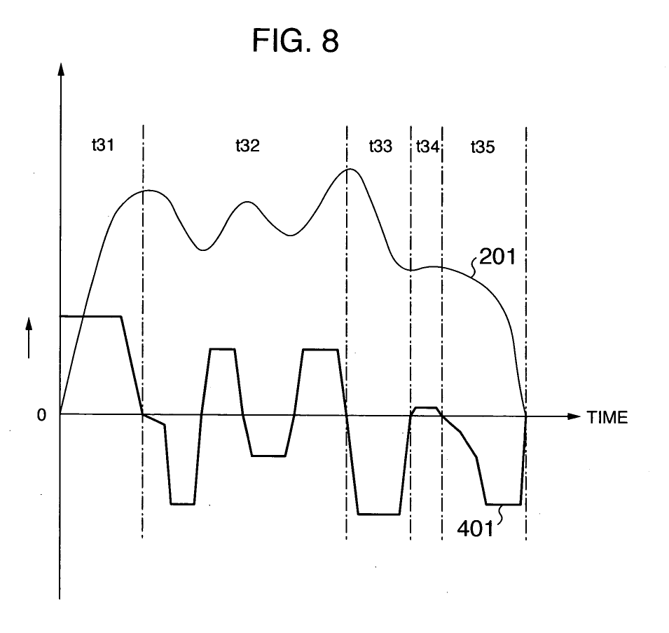

FIG. 8 is a time chart showing the relation between the time series information, the feature amount, and the interval division.

When the interval detection unit 302 updates the interval information using the displacement 503, the interval information is divided again in five intervals from t31 to t35 as shown in FIG. 8.

In this decision rule the intervals in which the absolute values of the displacement 503 are less than 50 are decided to be the same intervals. As a result, from t12 to t15 are decided to be the same intervals.

The feature amount calculation method for how to calculate the feature amount is previously provided in the feature amount extraction unit 301 as a program. The interval calculation method for calculating where is to be designated as the change point and from where to where the intervals are the same using the feature amount is previously provided in the interval detection unit 302 as a program.

In this embodiment a primary linear differential value, etc. are calculated as the feature amount, but the program may be modified as the need arises and values which can be obtained by the time frequency analysis such as Fourier transform and wavelet transformation or other calculation methods may be used as the feature amount.

Here, it is assumed that the interval information and the feature amount 401, the change rate 501, the change rate peak 502, and the displacement 503 have been output to the state estimation unit 102.

In FIG. 8, the intervals are primarily classified with t31 interval as the “acceleration”, t32 interval as the “cruising”, t33 interval as the “deceleration”, t34 interval as the “cruising”, and t35 interval as the “deceleration”.

The interval classification unit 601 within the state estimation unit 102 outputs this primary classification information to the interval relation decision unit 602.

The interval relation decision unit 602 previously keeps the state transition information corresponding to the equipment, and compares the primary classification information with the state transition information which it previously keeps and decides whether the state of the classified interval is appropriate or not.

In this embodiment the interval relation decision unit 602 is assumed to keep information corresponding to the state transition FIG. 1101. The t31 interval is classified as the “acceleration” state and the t32 interval is classified as the “cruising”.

In the state transition FIG. 1101 of FIG. 3, as it is assumed that it is possible to transform from the “acceleration” state to the “cruising” state the interval relation decision unit 602 decides that the relation between the t31 interval and the t32 interval is correct.

Next, as the t33 interval is classified as the “deceleration” and the t32 interval is the “cruising”, similarly the interval relation decision unit 602 decides that the relation between the t32 interval and the t33 interval is also correct.

Next, the t34 interval is classified as the “cruising” but there is no transition from the “deceleration” to the “cruising” in the state transition FIG. 1101.

Consequently, the interval relation decision unit 602 decides that the relation between the t33 interval and the t34 interval is not correct.

Subsequently, about the relation between the t34 interval and the t35 interval, as it is from the “cruising” to the “deceleration” the interval relation decision unit 602 decides that it is correct.

The interval relation decision unit 602 outputs a decision result to the state decision unit 603.

The state decision unit 603 searches part in which the interval relation is not correct among received decision result and modifies the classification of the interval to be correct relation.

Here, as the relation between the t33 interval and the t34 interval has been decided not to be correct, it decides that the classification of the t34 interval is not correct and modifies the classification of the t34 interval to the “deceleration” using the interval classification result of the t33 and the t35.

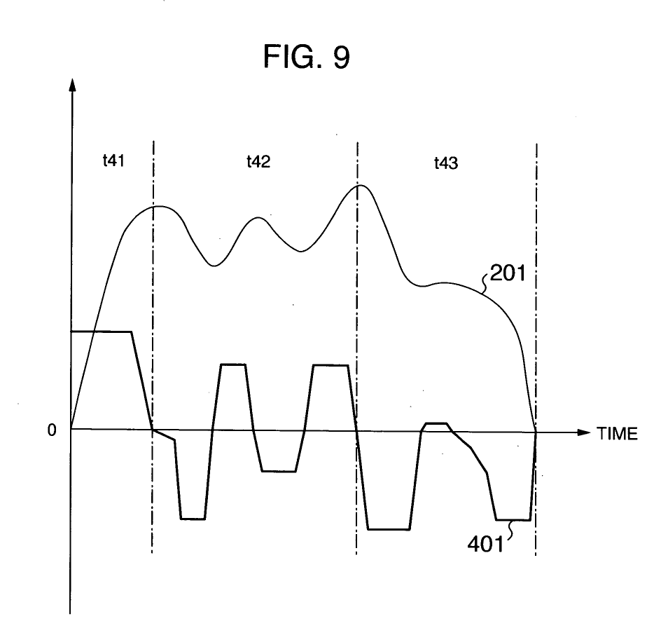

FIG. 9 is a time chart showing the relation between the time series information, the feature amount, and the interval division.

Finally, from the t33 interval to the t35 interval it is classified as the “deceleration”, the state decision unit 603 updates the interval information and outputs the interval information of from t41 to t43 as shown in FIG. 9 and the state information of each (t41 is the “acceleration”, t42 is the “cruising”, t43 is the “deceleration”) to the equipment diagnosis unit 103.

In this embodiment, it is decided about the relation of an interval between an interval immediately before and an interval immediately after. It is possible to decide not only the interval immediately before and the interval immediately after but also about the relation of an interval between an interval a plurality of intervals before and an interval a plurality of intervals after referring to the state transition information according to the complexity, etc. of the state transition information.

Also in this embodiment, it has been shown about a piece of time series information but if it is decided at the same time about a plurality of other time series information, more precise interval information and state information can be output.

For example, in the example of the car if not only the speed information but also the information such as the number of revolutions of engine and the degree of opening of accelerator are used, the state information considering also an upward slope or a downward slope can be output.

If the operation information of the wiper is used and a variety of information such as distinguishing running in fine weather and running in rainy weather is treated at the same time, the sate of the car can be decided more accurately.

If the state is decided using only the information of each interval, the correct state decision can not always be done.

If the sate is compared with and referred to the state transition information about how the relationship between the intervals each other is, an appropriate interval division and state decision can be done.

The equipment diagnosis unit 103 diagnoses the equipment most appropriately per interval using the interval information, the state information, and the original time series information which it has received.

According to the present invention, as it distinguishes the operation state, the operation environment, and the operation condition of the equipment, estimates the state of the equipment based on the before and after relation of the time series information, and diagnoses the state of the equipment properly according to the estimated state, the diagnosis precision can be enhanced.

It should be further understood by those skilled in the art that although the foregoing description has been made on embodiments of the invention, the invention is not limited thereto and various changes and modifications may be made without departing from the spirit of the invention and the scope of the appended claims.

1. A diagnosis apparatus for diagnosing state of equipment comprising:
an interval estimation unit which receives time series information from diagnosis object equipment and detects a change point of the time series information;
a state estimation unit which receives the time series information from the diagnosis object equipment and change point information from the interval estimation unit, divides the time series information temporally with the change point as a boundary, and estimates a state of the equipment from before and after relation of an interval or relation with another time series information per divided interval; and,
an equipment diagnosis unit which diagnoses the equipment according to an estimated state.

2. A diagnosis apparatus for diagnosing state of equipment according to claim 1, wherein the state of the equipment which the state estimation unit estimated includes an operation state, an operation environment, and an operation condition of the equipment.

3. A diagnosis apparatus for diagnosing state of equipment comprising an interval estimation unit which receives time series information from diagnosis object equipment and detects a change point of the time series information, a state estimation unit which receives the time series information from the diagnosis object equipment and change point information from the interval estimation unit, divides the time series information temporally with the change point as a boundary, and estimates a state of the equipment from before and after relation of an interval or relation with another time series information per divided interval, and an equipment diagnosis unit which diagnoses the equipment according to an estimated state, wherein:
the interval estimation unit is provided with a feature amount extraction unit and an interval detection unit;
the feature amount extraction unit calculates a feature amount of the time series information received from the diagnosis object equipment, sends a calculated feature amount and the time series information before the calculation process to the interval detection unit;
the interval detection unit divides the time series information temporally using a received feature amount and returns divided interval information to the feature amount extraction unit;
the feature amount extraction unit calculates another feature amount per divided interval based on received interval information, sends another calculated feature amount to the interval detection unit; and,
the feature amount extraction unit and the interval detection unit alternately perform the calculation of the feature amount and the calculation of the interval information and output final interval information and feature amount to the state estimation unit.

4. A diagnosis apparatus for diagnosing state of equipment comprising an interval estimation unit which receives time series information from diagnosis object equipment and detects a change point of the time series information, a state estimation unit which receives the time series information from the diagnosis object equipment and change point information from the interval estimation unit, divides the time series information temporally with the change point as a boundary, and estimates a state of the equipment from before and after relation of an interval or relation with another time series information per divided interval, and an equipment diagnosis unit which diagnoses the equipment according to an estimated state, wherein:
the state estimation unit is provided with an interval classification unit, an interval relation decision unit, and a state decision unit;
the interval classification unit calculates to which state each interval is classified using received interval information and feature amount;
the interval relation decision unit, which previously keeps state transition information corresponding to the equipment, compares primary classification information with the state transition information which it previously keeps, decides whether a state of classified interval is correct or not; and,
the state decision unit searches part in which interval relation is not correct among received decision results, modifies the classification of the interval to be correct relation, and outputs interval information and state information of each to the equipment diagnosis unit.

5. A diagnosis apparatus for diagnosing state of equipment according to claim 4, wherein:
the state estimation unit is provided with a unit to change the state transition information to be compared with according to an instruction of an operator of the diagnosis apparatus for diagnosing state of equipment.

6. A diagnosis apparatus for diagnosing state of equipment according to claim 4, wherein:
the state estimation unit is provided with a unit to change a number of the intervals before and after to be compared with according to an instruction of an operator of the diagnosis apparatus for diagnosing state of equipment.

7. A diagnosis apparatus for diagnosing state of equipment according to claim 4, wherein:
the state estimation unit is provided with a unit to change a number of the kinds of the state transition information to be compared with according to an instruction of an operator of the diagnosis apparatus for diagnosing state of equipment.
